(19) United States
(12) Patent Application Publication
(10) Pub. No.: US 2007/0238035 A1
(43) Pub. Date: Oct. 11, 2007

(54) Method and apparatus defining a color filter array for an image sensor

(75) Inventors: Richard D. Holscher, Boise, ID (US); Ulrich C. Boettiger, Boise, ID (US)

Correspondence Address: DICKSTEIN SHAPIRO LLP, 1825 EYE STREET, NW, WASHINGTON, DC, 20006, US

(73) Assignee: MICRON TECHNOLOGY, INC.

(21) Appl. No.: 11/399,314

(22) Filed: Apr. 7, 2006

(51) Int. Cl. G02B 5/20; H01L 31/0232; H01L 31/00

(52) U.S. Cl. 430/7; 257/440

(57) ABSTRACT

An apparatus and method to provide an imager having an array of color filter elements, each color filter element being separated from each other by spacers. The spacers can optically isolate filter elements from each other.

### FIELD OF THE INVENTION

The present invention relates to color filters for use in a solid-state image sensor and, in particular, to a color filter array having a structure that isolates individual colors from each other, and a method of forming the same.

### BACKGROUND OF THE INVENTION

Solid-state image sensors, also known as imagers, were developed in the late 1960s and early 1970s primarily for television image acquisition, transmission, and display. An imager absorbs incident radiation of a particular wavelength (such as optical photons, x-rays, or the like) and generates an electrical signal corresponding to the absorbed radiation. There are a number of different types of semiconductor-based imagers, including charge coupled devices (CCDs), photodiode arrays, charge injection devices (CIDs), hybrid focal plan arrays, and CMOS imagers. Current applications of solid-state imagers include cameras, scanners, machine vision systems, vehicle navigation systems, star trackers, and motion detector systems, among other uses.

These imagers typically consist of an array of pixels containing photosensors, where each pixel produces a signal corresponding to the intensity of light impinging on its photosensor when an image is focused on the array. These signals may then be stored, for example, for later display, printing, or analysis or are otherwise used to provide information about the optical image. The photosensors are typically phototransistors, photogates, or photodiodes. The magnitude of the signal produced by each pixel, therefore, is proportional to the amount of light impinging on the photosensor.

To allow the photosensors to capture a color image, the photosensors must be able to separately detect, e.g., red (R) photons, green (G) photons and blue (B) photons. Accordingly, each pixel must be sensitive only to one color or spectral band. For this, a color filter array (CFA) is typically placed in front of the pixels so that each pixel measures the light of the color of its associated filter. Thus, each pixel of a color imager is covered with either a red, green, or blue filter, according to a specific pattern.

Color filter arrays are commonly arranged in a mosaic sequential pattern of red, green, and blue filters known as a Bayer filter pattern. The Bayer filter pattern is quartet-ordered with successive rows that alternate red and green filters, then green and blue filters. Thus, each red filter is surrounded by four green and four blue filters, while each blue filter is surrounded by four red and four green filters. In contrast, each green filter is surrounded by two red, four green, and two blue filters. The heavy emphasis placed upon green filters is due to human visual response, which reaches a maximum sensitivity in the 550-nanometer (green) wavelength region of the visible spectrum. U.S. Pat. No. 3,971,065 to Bayer describes the Bayer pattern color filter array.

To form the color filter array, a negative resist is typically used containing a color pigment. The Bayer pattern requires the printing and patterning of three negative resist layers on a passivation layer, each of a respective color. The individual color filters are adjacent one another in the computed color filter array.

However, the negative resist has poor resolution, and suffers from shrinkage and poor planarity which affects the optical properties of the color filter array. Moreover, when patterning the photoresist layer, a transparent film must be used on the substrate so the exposure tool can align the pattern over the pixels through the film in order to separate the color filter elements.

Another disadvantage to this approach is that bonding pads usually are exposed prior to formation of color filter layers. Thus, chemicals used in the formation of color filter layers can become trapped in the bonding pad area and cause reliability problems and corrode the bonding pad metallization.

In addition, when printing the photoresist, no layer separates the color filter elements from each other to block stray light between pixels, thus resulting in optical crosstalk.

Accordingly, there is a need and desire for an improved structure for the color filter array which more effectively and accurately defines the color filter array colors and provides improved optical crosstalk and improved color separation with a minimum of added complexity to the manufacturing process and/or increase in fabrication costs. A method of fabricating a color filter array exhibiting these improvements is also needed.

### BRIEF SUMMARY OF THE INVENTION

Exemplary embodiments of the invention provide an imager having an array of color filter elements in which spacers are provided between the color filter elements. The spacers can separate colors from each other (particularly during fabrication) to more accurately define the color filter array colors. In addition, the spacers may be comprised of an opaque material to serve as light blocks surrounding the pixels, thus reducing optical crosstalk between pixels. The spacer material may also serve as a light block covering the periphery circuitry outside a pixel array.

Also provided are methods of forming a color filter array. In one exemplary method embodiment, a color filter array is produced by forming spacers which define the regions of each color filter element, in order to separate colors and reduce optical crosstalk. The color filter elements are provided in regions defined by the spacers.

### BRIEF DESCRIPTION OF THE DRAWINGS

These and other features and advantages of the invention will be more apparent from the following detailed description that is provided in connection with the accompanying drawings and illustrated exemplary embodiments of the invention, in which:

FIG. 1 illustrates a cross-sectional view of an exemplary embodiment of a color filter array constructed in accordance with the invention;

FIG. 2A illustrates a cross-sectional view of a first processing stage for the fabrication of a color filter array in accordance with one exemplary embodiment of the invention;

FIG. 2B illustrates a cross-sectional view of a processing stage subsequent to that shown in FIG. 2A;

FIG. 2C illustrates a cross-sectional view of a processing stage subsequent to that shown in FIG. 2B;

FIG. 2D illustrates a cross-sectional view of a processing stage subsequent to that shown in FIG. 2C;

FIG. 2E illustrates a cross-sectional view of a processing stage subsequent to that shown in FIG. 2D;

FIG. 2F illustrates a cross-sectional view of a processing stage subsequent to that shown in FIG. 2E;

FIG. 2G illustrates a top-down view of the processing stage shown in FIG. 2F;

FIG. 2H illustrates a cross-sectional view of a processing stage subsequent to that shown in FIG. 2G;

FIG. 2I illustrates a cross-sectional view of a processing stage subsequent to that shown in FIG. 2H;

FIG. 2J illustrates a cross-sectional view of a processing stage subsequent to that shown in FIG. 2I;

FIG. 3 illustrates a cross-sectional view of an exemplary color filter array constructed in accordance with another exemplary embodiment of the invention;

FIG. 4A illustrates a cross-sectional view of a first processing stage for the fabrication of a color filter array in accordance with another exemplary embodiment of the invention;

FIG. 4B illustrates a cross-sectional view of a processing stage subsequent to that shown in FIG. 4A;

FIG. 4C illustrates a cross-sectional view of a processing stage subsequent to that shown in FIG. 4B;

FIG. 4D illustrates a cross-sectional view of a processing stage subsequent to that shown in FIG. 4C;

FIG. 5 is a block diagram of a CMOS imager constructed in accordance with the invention; and

FIG. 6 is a block diagram of a processor system incorporating at least one imager device constructed in accordance with an embodiment of the invention.

### DETAILED DESCRIPTION OF THE INVENTION

In the following detailed description, reference is made to the accompanying drawings, which form a part hereof and illustrate specific embodiments in which the invention may be practiced. In the drawings, like reference numerals describe substantially similar components throughout the several views. These embodiments are described in sufficient detail to enable those skilled in the art to practice the invention, and it is to be understood that other embodiments may be utilized, and that structural, logical and electrical changes may be made without departing from the spirit and scope of the present invention.

The term “substrate” is to be understood as including silicon, silicon-on-insulator (SOI), silicon-on-sapphire (SOS), and silicon-on-nothing (SON) technology, doped and undoped semiconductors, epitaxial layers of silicon supported by a base semiconductor foundation, and other semiconductor structures. Furthermore, when reference is made to a “substrate” in the following description, previous process steps may have been utilized to form regions or junctions in the base semiconductor structure or foundation. In addition, the semiconductor need not be silicon-based, but could be based on silicon-germanium, germanium, or gallium-arsenide.

The term “pixel” or “pixel cell” refers to a picture element unit cell containing a photo-conversion device and transistors for converting electromagnetic radiation to an electrical signal. For purposes of illustration, a representative three-color R, G, B pixel array is described herein; however, the invention is not limited to the use of an R, G, B array, and can be used with other color arrays, one example being C, M, Y, K (which represents cyan, magenta, yellow, and black color filters). Also, for purposes of illustration, a portion of a representative pixel is illustrated in the figures and description herein, and typically fabrication of all pixels in an imager will proceed concurrently and in a similar fashion.

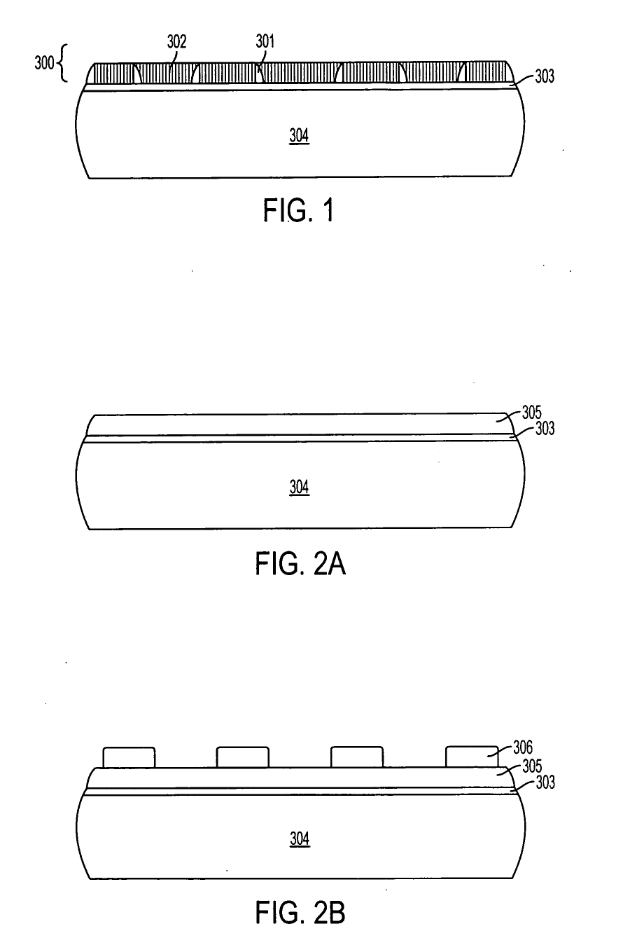

Although the invention is described in relation to use with a CMOS imager, the invention is not so limited and has applicability to any solid-state imager. Referring now to the drawings, where like elements are designated by like numerals, FIG. 1 illustrates an exemplary embodiment of a color filter array 300 formed in accordance with an exemplary embodiment of the invention. The color filter array 300, which is formed over a substrate 304 on which a various array of pixels have been fabricated and a passivation layer 303, includes spacers 301 in between the color filter elements 302 to separate the individual color filter elements 302 from each other. Each spacer 301 is preferably constructed of an opaque material that would function effectively as a light block to reduce optical crosstalk between pixels underneath the color filter array 300.

Different materials can be used to form the spacers 301. For example, the spacers 301 may comprise any material that substantially operates to either absorb or reflect incoming light. For example, the spacers 301 may comprise a metal, such as aluminum, metal alloy, or metal silicides. The spacers 301 also may comprise a polysilicon material, which is opaque at shorter wavelengths of incoming light. Spacer 301 material can also be used with any other suitable, non-metallic materials to block or reflect the intensity of stray light. Therefore, the spacers 301 reduce optical crosstalk and form a light block between pixels and more accurately define color filter array boundaries and colors.

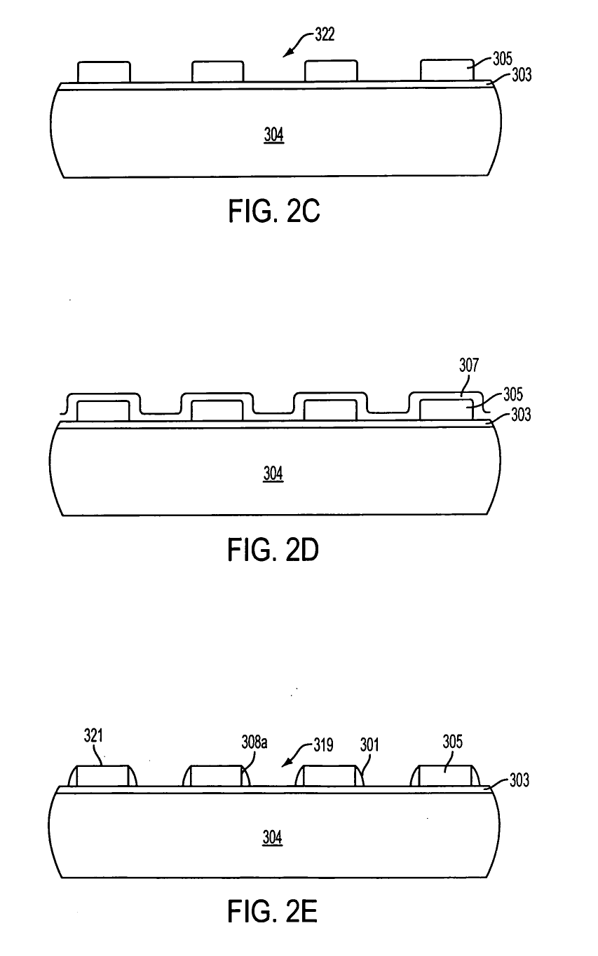

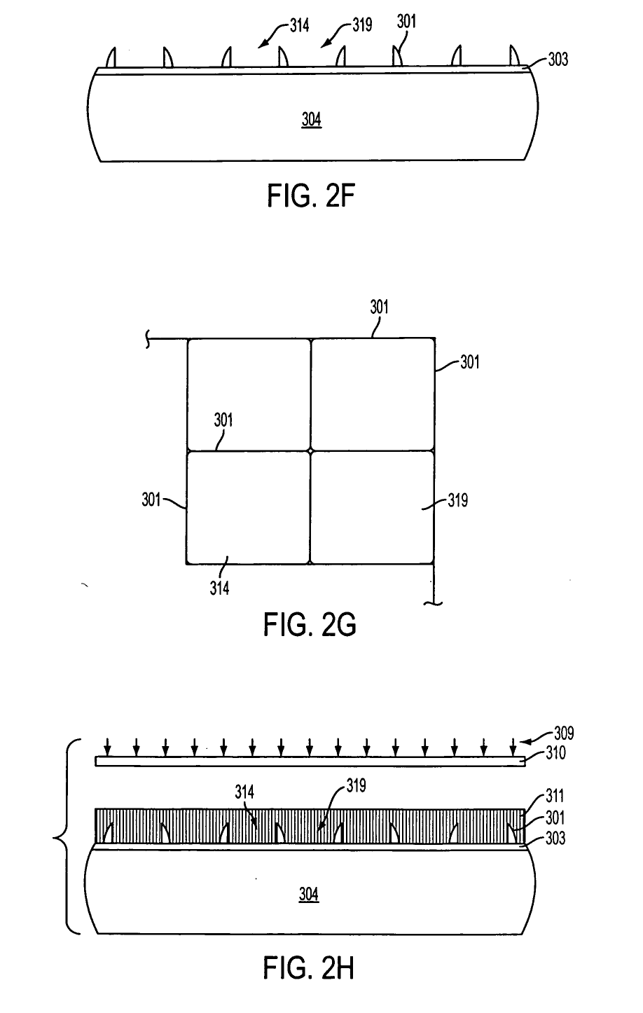

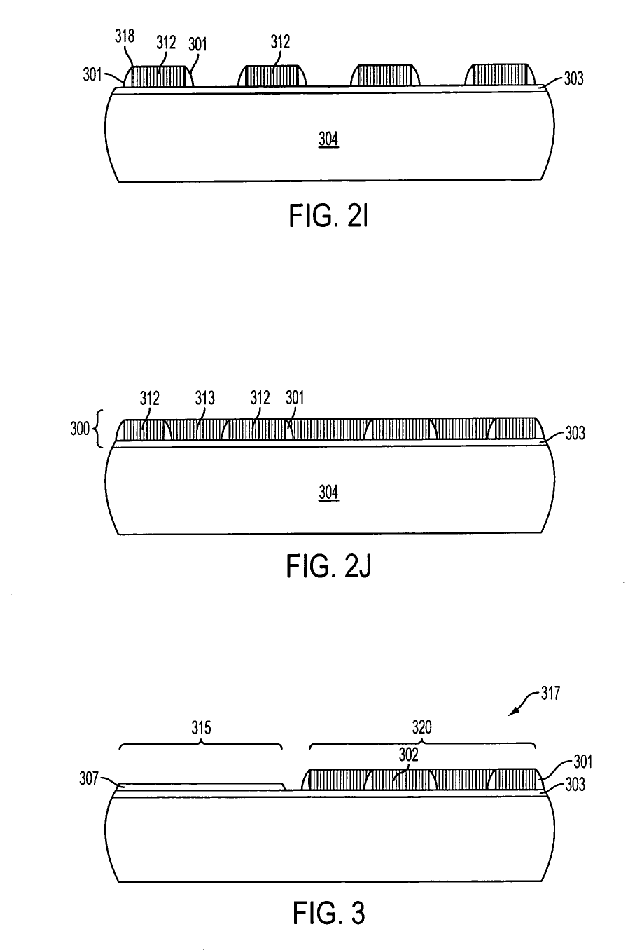

FIGS. 2A-2J depict the formation of color filter array 300 according to an exemplary embodiment of the invention. The steps described herein need not be performed in any particular order, except for those logically requiring the results of prior actions. Accordingly, while the steps below are described as being performed in a general order, the order is exemplary only and can be altered if desired.

As illustrated in FIG. 2A, a passivation layer 303 is formed over an imager substrate 304, which has been fabricated to include an array of pixels, peripheral circuitry, and interconnect metallization layers. The pixels, peripheral circuitry, and metallization layers are not shown in the figures for convenience purposes. The passivation layer 303 is formed, for example, of a phospho-silicate-glass (PSG), silicon nitride, or oxynitride. Although only one passivation layer 303 is shown, more than one passivation layer may be formed. A transparent carbon layer 305 is formed on the passivation layer. It should be noted that layer 305 may instead be any transparent material, such as an oxide, silicon dioxide, silicon nitride, an oxynitride, or tetraethyl orthosilicate (TEOS), among others which can be easily etched. The carbon layer 305 has a thickness as required for the color filters, for example, approximately 1,000 Å to approximately 20,000 Å. The carbon layer 305 is deposited using conventional methods such as a chemical vapor deposition (CVD).

The use of a transparent carbon layer 305 over a pixel creates advantages because of the inherent properties of the material. Specifically, carbon materials permit a high temperature operation and remain thermally stable and rigid. Further, the carbon layer 305 can be etched with good selectivity to the passivation layer 303 and bonding pads (not shown).

FIG. 2B depicts a patterned photoresist layer 306 formed on the carbon layer 305 to be used as a mask for a subsequent etching process. Photolithographic exposure is used to pattern the photoresist layer 306. The light source used for the photolithographic process carried out on the photoresist layer 306 has a wavelength of e.g., about 365 nanometers, or any wavelength providing the required lithographic resolution.

As shown in FIG. 2C, the photoresist layer 306 (FIG. 2B) is an etch mask, such that the carbon layer 305 is etched to form openings 322 extending therethrough and stopping at the passivation layer 303. The photoresist layer 306 (FIG. 2B) is removed using selective photoresist stripping techniques, preferably by a wet etch or a dry etch. The stripping technique should remove the photoresist layer 306 selective to the carbon layer 305. For example, a wet process, such as Micron's “SC1” process, that has reasonable selectivity to carbon can be used. A hard mask layer (not shown), such as an oxide or dielectric-antireflective coating (ARC), may also be applied on top of the carbon layer 305 prior to applying the photoresist layer 306. The hard mask may be needed to adequately etch the carbon layer 305 selective to the photoresist layer 306.

A third layer 307, between approximately 500 Å and approximately 3,000 Å thick, is formed on the etched carbon layer 305 and passivation layer 303, as shown in FIG. 2D. The third layer 307 will be used to form spacers 301 in FIG. 2E. The third layer 307 may be formed of any opaque material, such as a metal, metal alloy, metal silicides, aluminum, or other opaque material. The third layer 307 may also be formed of a polysilicon material, which is opaque at shorter wavelengths of incoming light. The third layer 307 is formed at a low temperature of less than 400° C. The third layer 307 may be applied by any suitable conformal technique, including one or more spin-on techniques or any other technique for conformal material deposition, such as CVD or physical vapor deposition (PVD).

FIG. 2E illustrates the formation of spacers 301 on the carbon layer sidewalls 308a and over a portion of the passivation layer 303. The spacers 301 can be formed by any known technique. For example, an unmasked process (not shown) is preferable to etch the third layer 307 (FIG. 2D) to form an opening 319 extending therethrough, which stops on the passivation layer 303. The top surface 321 of the underlying carbon layer 305 is also revealed by the etching process. If a hard mask layer (not shown) is used, as discussed above, then the top surface revealed would be the hard mask, not the carbon layer 305. The third layer 307 can also be etched using a patterned photoresist layer (not shown). The unmasked or patterned photoresist process leaves the spacers 301 on the carbon layer sidewalls 308a and over a portion of the passivation layer 303.

A standard etching technique can be used to strip the carbon layer 305, leaving only spacers 301 and forming openings 314, over portions of the passivation layer 303, as shown in FIG. 2F. For instance, the carbon layer 305 is stripped with or without photoresist patterning. The stripping technique used effectively etches the carbon layer 305 to reveal the underlying passivation layer 303. If a hard mask layer (not shown) is used, as discussed above, a process should be used to remove the hard mask prior to removing the carbon layer 305. FIG. 2G is a top-down view of the spacers 301 at a corner portion of a pixel array showing how the spacers 301 define regions 319 and 314 for color filter elements.

A color filter array is next formed. Using conventional procedures, a red negative photoresist layer 311 is formed over the passivation layer 303, the spacers 301, and in the openings 314 and 319, as shown in FIG. 2H. A light source 309, such as an i-line light source of e.g., 365 nanometers, shines on a photomask 310 and exposes a portion of the red photoresist layer 311. A develop processing step is conducted to remove the unexposed red photoresist layer 311, thus producing a red color filter element 312, as shown in FIG. 2I. For example, standard lithography can be used to remove the red photoresist layer 311 until the color pigment of the red color filter element 312 reaches the top 318 of the spacers 301. Thus, spacers 301 separate the color filter elements 302 from each other (FIG. 1). The steps as illustrated in FIG. 2H and FIG. 2I are performed two more times with green and blue photoresist layers to form green color filter elements and blue color filter elements. After forming the red, green, and blue color filter elements, an optional chemical mechanical polish (CMP) step can be conducted to remove any unexposed color pigment. The top 318 of the spacers 301 functions as an etch-stop during the CMP step of removing excess color pigment. FIG. 2J illustrates one row of a pixel array in a cross section showing alternating red and green color filter elements 312 and 313. This leaves a pattern for the color filter array 300 of alternating color filter elements with spacers 301 formed between and defining the regions for the color filter elements. In this way, the spacers 301 function to separate the color filter array 300 colors in order to more accurately define the array boundaries and colors. In addition, the spacers 301 function as light blocks, thus reducing optical crosstalk between pixels.

FIG. 3 depicts a portion 317 of an imager in accordance with another exemplary embodiment of the invention. In the imager 317, a third layer 307, in addition to forming spacers 301 in the pixel array region 320, is used as a light block over a periphery region 315, adjacent a pixel array color filter region 320.

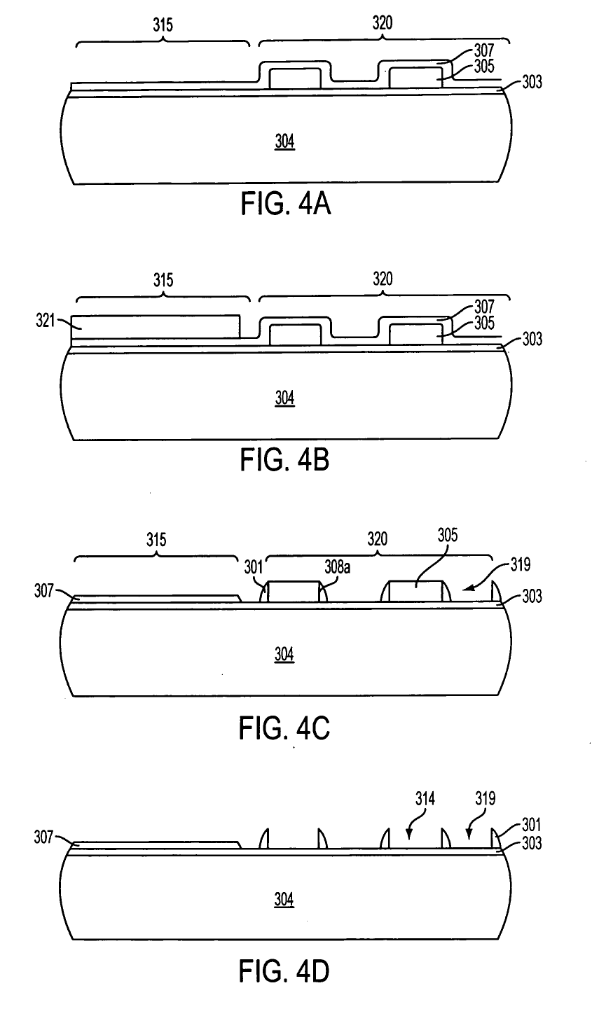

The formation of the FIG. 3 structure is now described with reference to FIGS. 4A-4D. Referring to FIG. 4A, the passivation layer 303 is formed over a substrate 304, as described above with reference to FIG. 2A. The carbon layer 305 is formed over the passivation layer 303 and etched to form a pattern over the pixel array region 320 the passivation layer 303, as described above with respect to FIGS. 2A-2C, and is removed from the periphery region 315 outside the pixel array. The third layer 307 is deposited over the passivation layer 303 and the carbon layer 305 in the pixel array region 320 as well as over the passivation layer 303 in the periphery region 315. The third layer 307 is deposited with a thickness of approximately 500 Å to approximately 3,000 Å. The third layer 307 may substantially absorb or reflect incoming light to function as an effective light block between pixels in the pixel array region 320 and over the periphery region 315 outside the pixel array. The third layer 307 is formed of the same materials as described above with reference to FIGS. 2A-2J.

The third layer 307 is removed by an etching technique and may be selectively removed in the color filter array region 320, but not in the periphery region 315. The third layer 307 forms a light block over the periphery region 315. This can be done by covering the periphery region 315 with a photoresist layer 321, as illustrated in FIG. 4B. Other portions of the third layer 307 are etched away to form openings 319, while leaving the third layer 307 to form spacers 301 along the sidewalls 308a of the carbon layer 305, as illustrated in FIG. 4C. It is also possible to complete the etching step without a photoresist layer. Similar to the steps recited above and illustrated in FIG. 4D, the carbon layer 305 is etched away to form openings 314 and to reveal portions of the passivation layer 303 and leave spacers 301. As described and illustrated above with respect to FIG. 3, the openings 314 and 319 in FIG. 4D are filled with a color filter element 302, using the color filling techniques discussed above, with respect to FIGS. 2H-2J. Thus, in addition to separating the color filter elements 302, the spacers 301 serve as light blocks between the pixels in the pixel array region 320. Moreover, the third layer 307 formed on the periphery region 315 outside the pixel array substantially blocks all light transmitted on the periphery, thus reducing optical crosstalk and reducing the effect of light on transistors in the periphery region 315.

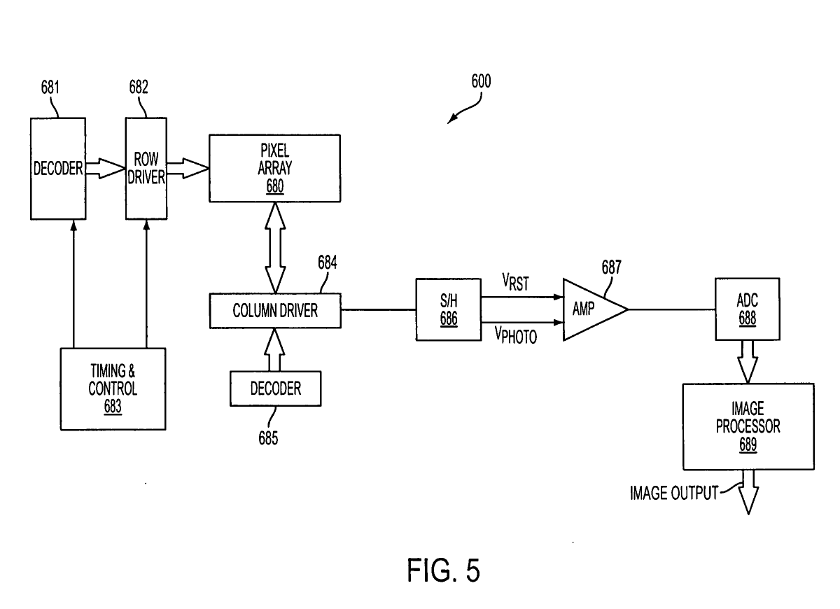

A typical single chip CMOS imager 600, which may use the color filter array of the invention, is illustrated by the block diagram of FIG. 5. The imager 600 includes a pixel array 680 having pixels and a color filter array constructed as described above. The pixels of array 680 are arranged in a predetermined number of columns and rows.

The rows of pixels in array 680 are read out one by one. Accordingly, pixels in a row of array 680 are all selected for readout at the same time by a row select line, and each pixel in a selected row provides a signal representative of received light to a readout line for its column. In the array 680, each column also has a select line, and the pixels of each column are selectively read out onto output lines in response to the column select lines.

The row lines in the array 680 are selectively activated by a row driver 682 in response to row address decoder 681. The column select lines are selectively activated by a column driver 684 in response to column address decoder 685. The array 680 is operated by the timing and control circuit 683, which controls address decoders 681, 685 for selecting the appropriate row and column lines for pixel signal readout.

The signals on the column readout lines typically include a pixel reset signal (Vᵣₛₜ) and a pixel image signal (Vₚₕₒₜₒ) for each pixel. Both signals are read into a sample and hold circuit (S/H) 686. A differential signal (Vᵣₛₜ−Vₚₕₒₜₒ) is produced by differential amplifier (AMP) 687 for each pixel, and each pixel's differential signal is digitized by analog-to-digital converter (ADC) 688. The analog-to-digital converter 688 supplies the digitized pixel signals to an image processor 689, which performs appropriate image processing before providing digital signals defining an image output.

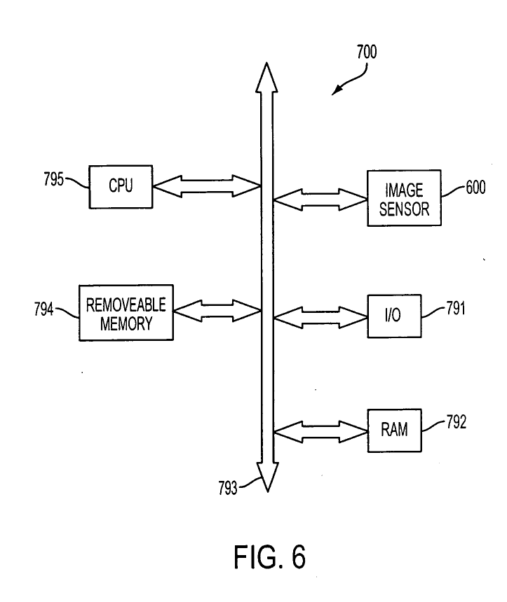

FIG. 6 illustrates a processor system 700 including the imager 600 of FIG. 5. The processor system 700 is exemplary of a system having digital circuits that could include imagers. Without being limiting, such a system could include a computer system, camera system, scanner, machine vision, vehicle navigation, video phone, surveillance system, auto focus system, star tracker system, motion detection system, and other systems supporting image acquisition.

The processor system 700, for example a camera system, generally comprises a central processing unit (CPU) 795, such as a microprocessor, that communicates with an input/output (I/O) device 791 over a bus 793. Imager 600 also communicates with the CPU 795 over bus 793. The processor system 700 also includes random access memory (RAM) 792, and can include removable memory 794, such as flash memory, which also communicate with CPU 795 over the bus 793. Imager 600 may be combined with a processor, such as a CPU, digital signal processor, or microprocessor, with or without memory storage on a single integrated circuit or on a different chip than the processor.

It is again noted that the above description and drawings are exemplary and illustrate preferred embodiments that achieve the objects, features and advantages of the present invention. It is not intended that the present invention be limited to the illustrated embodiments. Any modification of the present invention which comes within the spirit and scope of the following claims should be considered part of the present invention. For example, although described is the exemplary embodiment described with reference to a CMOS imager, the invention is not limited to CMOS imagers and can be used with other imager technology (e.g., CCD technology) as well.

What is claimed as new and desired to be protected by Letters Patent of the United States is:

1. A method of forming a color filter array, said method comprising the steps of:
forming a passivation layer over an array of pixels;
forming a plurality of spacers over said passivation layer to define regions for color filter elements;
and
forming a pattern of a plurality of said color filter elements within said regions defined by said spacers.

2. The method of claim 1, wherein said passivation layer is comprised of one of a phospho-silicate-glass, a silicon nitride, and an oxynitride.

3. The method of claim 1, wherein said step of forming said spacers further comprises:
forming a second layer over said passivation layer;
patterning said second layer to form regions exposing a top surface of said passivation layer;
forming a third layer over said passivation layer and a top of said patterned second layer and along sidewalls of said patterned second layer; and
forming said spacers from said third layer by removing portions of said third layer to reveal a top surface of said passivation layer and by removing said second layer.

4. The method of claim 3, wherein said second layer comprises a carbon containing layer.

5. The method of claim 3, wherein said second layer comprises carbon.

6. The method of claim 3, wherein said second layer comprises one of an oxide, a silicon dioxide, a silicon nitride, an oxynitride, and a tetraethyl orthosilicate.

7. The method of claim 3, wherein said second layer has a thickness of approximately 1,000 Å to approximately 20,000 Å.

8. The method of claim 3, wherein said third layer comprises a material that is opaque.

9. The method of claim 8, wherein said third layer absorbs incoming light.

10. The method of claim 8, wherein said third layer reflects incoming light.

11. The method of claim 3, wherein said third layer comprises polysilicon.

12. The method of claim 3, wherein said third layer comprises a metal.

13. The method of claim 12, wherein said third layer comprises a metal silicide.

14. The method of claim 12, wherein said third layer comprises an aluminum.

15. The method of claim 12, wherein said third layer comprises a metal alloy.

16. The method of claim 3, wherein said third layer has a thickness of approximately 500 Å to approximately 3,000 Å.

17. The method of claim 3, wherein said step of removing said portion of said third layer comprises etching.

18. The method of claim 3, further comprising the step of forming said third layer over said passivation layer at a periphery region outside of a pixel array.

19. The method of claim 18, wherein said third layer forms a light block over said periphery region.

20. The method of claim 1, wherein said pattern of color filter elements comprises a pattern of red color filter elements, blue color filter elements, and green color filter elements.

21. A color filter array comprising:
an array of color filter elements, said color filter elements being separated from each other by spacers formed between each color filter element.

22. The color filter array of claim 21, wherein said color filter elements further comprise a pattern of red color filter elements, blue color filter elements, and green color filter elements.

23. The color filter array of claim 21, wherein each spacer comprises a material that is opaque.

24. The color filter array of claim 23, wherein each spacer absorbs incoming light.

25. The color filter array of claim 23, wherein each spacer reflects incoming light.

26. The color filter array of claim 21, wherein each spacer comprises polysilicon.

27. The color filter array of claim 21, wherein each spacer comprises a metal.

28. The color filter array of claim 27, wherein each spacer comprises a metal silicide.

29. The color filter array of claim 27, wherein each spacer comprises an aluminum.

30. The color filter array of claim 27, wherein each spacer comprises a metal alloy.

31. The color filter array of claim 21, wherein each spacer optically isolates said color filter elements.

32. An imager comprising:
an array of imaging pixels; and
a color filter array over said array of pixels, wherein said color filter array comprises an array of color filter elements, said color filter elements being separated from each other by spacers formed between each color filter element.

33. The imager of claim 32, wherein said color filter elements further comprise a pattern of red color filter elements, blue color filter elements, and green color filter elements.

34. The imager of claim 32, wherein each spacer comprises a material that is opaque.

35. The imager of claim 34, wherein each spacer absorbs incoming light.

36. The imager of claim 34, wherein each spacer reflects incoming light.

37. The imager of claim 32, wherein each spacer comprises polysilicon.

38. The imager of claim 32, wherein each spacer comprises a metal.

39. The imager of claim 38, wherein each spacer comprises a metal silicide.

40. The imager of claim 38, wherein each spacer comprises an aluminum.

41. The imager of claim 38, wherein each spacer comprises a metal alloy.

42. The imager of claim 32, wherein each spacer optically isolates said color filter elements.

43. The imager of claim 32, further comprising:
a periphery region surrounding said array of pixels; and
a layer disposed over said periphery region.

44. The imager of claim 43, wherein said layer comprises a material that is opaque.

45. The imager of claim 44, wherein said layer absorbs incoming light.

46. The imager of claim 44, wherein said layer reflects incoming light.

47. The imager of claim 43, wherein said layer comprises polysilicon.

48. The imager of claim 43, wherein said layer comprises a metal.

49. The imager of claim 48, wherein said layer comprises a metal silicide.

50. The imager of claim 48, wherein said layer comprises an aluminum.

51. The imager of claim 48, wherein said layer comprises a metal alloy.

52. The imager of claim 43, wherein said layer forms a light block over said periphery region.

53. A system comprising:
a processor coupled to an imager, said imager comprising an array of imaging pixels; and
a color filter array over said array of pixels, wherein said color filter array comprises an array of color filter elements, said color filter elements being separated from each other by spacers formed between each color filter element.

54. The system of claim 53, wherein said color filter elements further comprise a pattern of red color filter elements, blue color filter elements, and green color filter elements.

55. The system of claim 53, wherein each spacer comprises a material that is opaque.

56. The system of claim 55, wherein each spacer absorbs incoming light.

57. The system of claim 55, wherein each spacer reflects incoming light.

58. The system of claim 53, wherein each spacer comprises polysilicon.

59. The system of claim 53, wherein each spacer comprises a metal.

60. The system of claim 59, wherein each spacer comprises a metal silicide.

61. The system of claim 59, wherein each spacer comprises an aluminum.

62. The system of claim 59, wherein each spacer comprises a metal alloy.

63. The system of claim 53, wherein each spacer optically isolates said color filter elements.

64. The system of claim 53, further comprising:
a periphery region surrounding said array of pixels; and
a layer disposed over said periphery region.

65. The system of claim 64, wherein said layer comprises a material that is opaque.

66. The system of claim 65, wherein said layer absorbs incoming light.

67. The system of claim 65, wherein said layer reflects incoming light.

68. The system of claim 64, wherein said layer comprises polysilicon.

69. The system of claim 64, wherein said layer comprises a metal.

70. The system of claim 69, wherein said layer comprises a metal silicide.

71. The system of claim 69, wherein said layer comprises an aluminum.

72. The system of claim 69, wherein said layer comprises a metal alloy.

73. The system of claim 64, wherein said layer forms a light block over said periphery region.
